(19) United States
(12) Patent Application Publication
(10) Pub. No.: US 2005/0133933 A1
(43) Pub. Date: Jun. 23, 2005

(54) Various structure/height bumps for wafer level-chip scale package

(75) Inventors: Chng Han Shen, Singapore (SG); Matthew Lim Eng Han, Singapore (SG)

Correspondence Address: STEPHEN B. ACKERMAN, 28 DAVIS AVENUE, POUGHKEEPSIE, NY, 12603, US

(73) Assignee: Advanpack Solutions Pte. Ltd.

(21) Appl. No.: 10/742,306

(22) Filed: Dec. 19, 2003

(51) Int. Cl. H01L 23/48

(52) U.S. Cl. 257/779

(57) ABSTRACT

A die comprising: a substrate; two or more various shaped bump structures having a solder line formed over the substrate; and an epoxy layer formed over the substrate. The epoxy layer having a top surface wherein: (a) the solder lines are below the top surface of the epoxy layer′; (b) the solder lines are above the top surface of the epoxy layer; or (c) some of the solder lines are below the top surface of the epoxy layer and some of the solder lines are above the top surface of the epoxy layer.

### FIELD OF THE INVENTION

The present invention relates generally to fabrication of semiconductor chip interconnection, and more specifically to bump fabrication for wafer level-chip scale packages (WL-CSP).

### BACKGROUND OF THE INVENTION

Improvements to bumps for wafer level-chip scale packages (WL-CSP) are needed.

U.S. Pat. No. 6,486,054 B1 to Fan et al. describes a method to achieve robust solder bump height.

U.S. Pat. No. 6,184,581 B1 to Cornell et al. describes a solder bump input/output pad for a surface mount circuit device with adjacent input/output pads also having triangular shapes or diamond shapes.

U.S. Pat. No. 5,926,731 to Coapman et al. describes a method for controlling solder bump shape and stand-off height.

U.S. Pat. No. 6,297,551 B1 to Dudderar et al. describes integrated circuit packages with improved EMI characteristics.

U.S. Pat. No. 4,430,690 to Chance et al. describes a low inductance MLC capacitor with metal impregnation and solder bar contact.

### SUMMARY OF THE INVENTION

Accordingly, it is an object of the present invention to provide an improved bump design for wafer level-chip scale packages.

Other objects will appear hereinafter.

It has now been discovered that the above and other objects of the present invention may be accomplished in the following manner. Specifically, a die comprising: a substrate; two or more various shaped bump structures having a solder line formed over the substrate; and an epoxy layer formed over the substrate. The epoxy layer having a top surface wherein: (a) the solder lines are below the top surface of the epoxy layer′; (b) the solder lines are above the top surface of the epoxy layer; or (c) some of the solder lines are below the top surface of the epoxy layer and some of the solder lines are above the top surface of the epoxy layer.

### BRIEF DESCRIPTION OF THE DRAWINGS

The features and advantages of the present invention will be more clearly understood from the following description taken in conjunction with the accompanying drawings in which like reference numerals designate similar or corresponding elements, regions and portions and in which:

FIGS. 1 and 2 schematically illustrate a first preferred embodiment of the present invention having the epoxy above the solder line with FIG. 1 being a cross-sectional view of FIG. 2 along line 1-1.

FIGS. 3 and 4 schematically illustrate a second preferred embodiment of the present invention having the epoxy below the solder line with FIG. 3 being a cross-sectional view of FIG. 4 along line 3-3.

FIGS. 5 and 6 schematically illustrate a third preferred embodiment of the present invention having the epoxy above and below the solder line with FIG. 5 being a cross-sectional view of FIG. 6 along line 5-5.

FIGS. 7 to 15 schematically illustrate the formation of a wafer level-chip scale package (WL-CSP) formed in accordance with the method of the present invention.

FIG. 16 schematically illustrates stacked die/chip mounting with variable height bumps.

FIG. 17 schematically illustrates a flip chip mounted to a dual height substrate with variable height bumps.

### DETAILED DESCRIPTION OF THE PREFERRED EMBODIMENTS

### First Embodiment

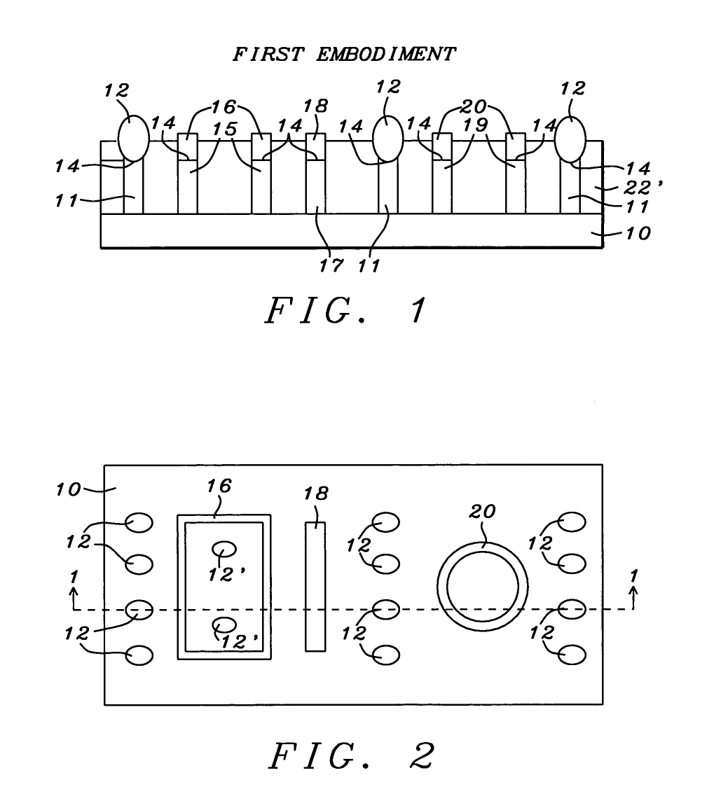

### Epoxy Layer 22′ Above the Solder Lines 14—FIGS. 1 and 2

As shown in FIG. 1, in the first embodiment of the present invention, the top of the epoxy layer 22′ is above the respective solder lines 14 of the various shaped bumps structures 11, 15, 17, 19 formed over the die/chip substrate 10.

Epoxy layer 22′ is preferably comprised of thermosetting resins or an underfill coating material.

FIG. 2 is a top down view of FIG. 1, with FIG. 1 being a cross-sectional view of FIG. 2 at line 1-1.

In the present invention, and again as more clearly shown in FIG. 2, the bump structures 11, 15, 17, 19 are of various shapes. For example the bump structures 11, 15, 17, 19 may be:
a) round bump structures 11 having a diameter of preferably from about 40 to 300 μm;) wall bump structures 16 forming, for example a square or rectangle, and having a width of preferably from about 40 to 300 μm and more preferably from about 100 to 200 μm; and, if rectangular, a length of preferably from about 300 to 3000 μm and more preferably from about 350 to 1200 μm;
c) bar bump structures 18 having a width of preferably from about 40 to 300 μm and having a length of up to about 300 μm and more preferably about 1500 μm that have excellent current carrying capacity; or
d) circular bump structures 19 having an outside diameter of preferably from about 150 to 3000 μm and an inside diameter of preferably from about 100 to 2500 μm.

Each bump structure 11, 15, 17, 19 includes respective solder 12, 16, 18, 20 thereover defining the solder lines 14. For the wall bump structures 16 forming, for example a square or rectangle, the square or rectangular structure may include internal (as shown in FIG. 2) or external bump structures 12′.

It is noted that other shapes are also possible.

These various shaped bump structures 11, 15, 17, 19 provide for enhanced electrical or thermal performance. A square or rectangle wall bump structure 16, for example, could be used as shielding for RF applications, e.g.: internal I/O may be noise sensitive; or RF shield, or a Faraday cage.

While FIG. 2 more clearly illustrates the various shapes of the bump structures 11, 15, 17, 19, FIG. 2 illustrates only a sample combination of such bump structures 11, 15, 17, 19 and does not limit the scope of the present invention.

### Second Embodiment

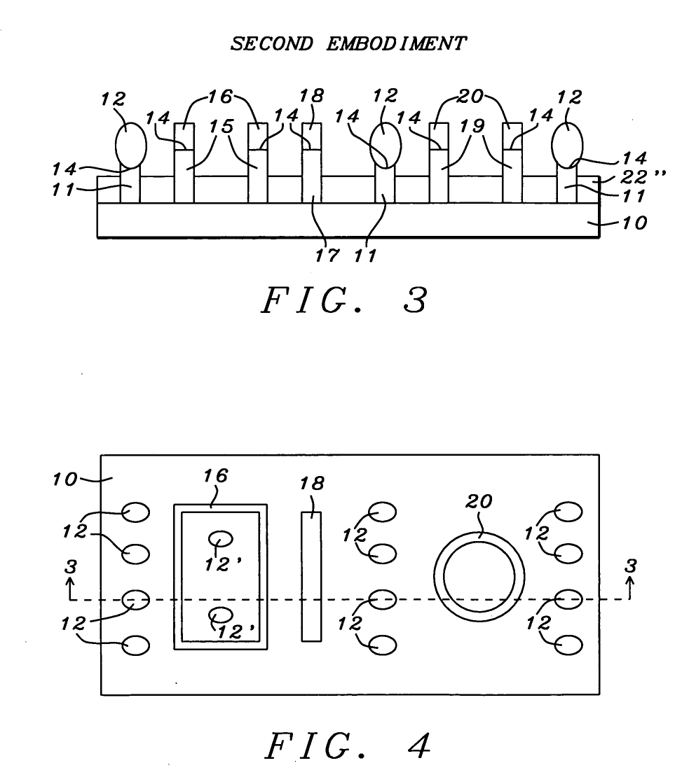

### Epoxy Layer 22″ Below the Solder Lines 14—FIGS. 3 and 4

As shown in FIG. 3, in the second embodiment of the present invention, the top of the epoxy layer 22″ is below the respective solder lines 14 of the various shaped bumps structures 11, 15, 17, 19 formed over the die/chip substrate 10.

Epoxy layer 22″ is preferably comprised of thermosetting resins or underfill coating material.

FIG. 4 is a top down view of FIG. 3, with FIG. 3 being a cross-sectional view of FIG. 4 at line 3-3.

In the present invention, and again as more clearly shown in FIG. 4, the bump structures 11, 15, 17, 19 are of various shapes. For example the bump structures 11, 15, 17, 19 may be:
a) round bump structures 11 having a diameter of preferably from about 40 to 300 μm; b) wall bump structures 16 forming, for example a square or rectangle, and having a width of preferably from about 40 to 300 μm and more preferably from about 100 to 200 μm; and, if rectangular, a length of preferably from about 300 to 3000 μm and more preferably from about 350 to 1200 μm;
c) bar bump structures 18 having a width of preferably from about 40 to 300 μm and having a length of up to about 3000 μm and more preferably about 1500 μm that have excellent current carrying capacity; or
d) circular bump structures 19 having an outside diameter of preferably from about 150 to 3000 μm and an inside diameter of preferably from about 100 to 2500 μm.

Each bump structure 11, 15, 17, 19 includes respective solder 12, 16, 18, 20 thereover defining the solder lines 14. For the wall bump structures 16 forming, for example a square or rectangle, the square or rectangular structure may include internal (as shown in FIG. 4) or external bump structures 12′.

It is noted that other shapes are also possible.

These various shaped bump structures 11, 15, 17, 19 provide for enhanced electrical or thermal performance. A square or rectangle wall bump structure 16, for example, could be used as shielding for RF applications, e.g.: internal I/O may be noise sensitive; or RF shield, or a Faraday cage.

While FIG. 4 more clearly illustrates the various shapes of the bump structures 11, 15, 17, 19, FIG. 4 illustrates only a sample combination of such bump structures 11, 15, 17, 19 and does not limit the scope of the present invention.

### Third Embodiment

### Epoxy Layer 22′ Below Solder Lines 214′ and Above Solder Lines 214″—FIGS. 5 and 6

It is noted that for stacked die or multi-tier substrates such as IC or MEMS applications, it is essential that the various shaped bump structures 211, 215, 217, 219 (11, 15, 17, 19) have two sets of heights.

As shown in FIG. 5, in the third embodiment of the present invention, the various shaped bumps structures 211, 215, 217, 219 comprise a first set of various shaped bumps structures 215, 217, 219 having a first height and a second set of various shaped bumps structures 211 having a second height that is less than the first height and thus, the top surface of the epoxy layer 22′″ is below solder lines 214′ of the various shaped bumps structures 215, 217, 219 and above the respective solder lines 214″ of the various shaped bumps structures 211 with each of the various shaped bumps structures 211, 215, 217, 219 formed over the die/chip substrate 10.

It is noted that the top of the epoxy layer 22′″ may be above/below any combination of the various shaped bumps structures 211, 215, 217, 219 as desired and FIGS. 5 and 6 illustrate just one example combination.

Epoxy layer 22′″ is preferably comprised of thermosetting resin or underfill coating material.

FIG. 5 is a top down view of FIG. 6, with FIG. 5 being a cross-sectional view of FIG. 6 at line 5-5.

In the present invention, and again as more clearly shown in FIG. 6, the bump structures 211, 215, 217, 219 are of various shapes. For example the bump structures 211, 215, 217, 219 may be:
a) round bump structures 211 having a diameter of preferably from about 40 to 300 μm; b) wall bump structures 216 forming, for example a square or rectangle, and having a width of preferably from about 40 to 300 μm and more preferably from about 100 to 200 μm; and, if rectangular, a length of preferably from about 500 to 3000 μm and more preferably from about 500 to 1500 μm;
c) bar bump structures 218 having a width of preferably from about 40 to 300 μm and having a length of up to about 3000 μm that have excellent current carrying capacity; or
d) circular bump structures 219 having an outside diameter of preferably from about 150 to 3000 μm and an inside diameter of preferably from about 100 to 2500 μm.

Each bump structure 211, 215, 217, 219 includes respective solder 212, 216, 218, 220 thereover defining the solder lines 214′, 214″. For the wall bump structures 216 forming, for example a square or rectangle, the square or rectangular structure may include internal (as shown in FIG. 6) or external bump structures 212′.

It is noted that other shapes are also possible.

These various shaped bump structures 211, 215, 217, 219 provide for enhanced electrical or thermal performance. A square or rectangle wall bump structure 216, for example, could be used as shielding for RF applications, e.g.: internal I/O may be noise sensitive; or RF shield, or a Faraday cage.

While FIG. 6 more clearly illustrates the various shapes of the bump structures 211, 215, 217, 219, FIG. 6 illustrates only a sample combination of such bump structures 211, 215, 217, 219 and does not limit the scope of the present invention.

Sequence of Formation of Bump Structures 11, 15, 17, 19: 211, 215, 217, 219 To Form Wafer Level-Chip Scale Package 100—FIGS. 7 to 15

FIGS. 7 to 15 illustrate the sequence in forming bump structures 11, 15, 17, 19; 211, 215, 217, 219 to form a wafer level-chip scale package (WL-CSP) 100 (it is noted that chip 100 may be a flip chip, for example). For ease of understanding and simplicity bump structures 11, 15, 17, 19; 211, 215, 217, 219 are represented by a single composite final bump structure(s) 90′″.

It is noted that FIG. 7 to 13 represent a portion of the complete wafer/die/chip substrate 10 as is shown in FIG. 14 and that FIG. 15 is a WL-CSP 100 cut from the entire wafer/die/chip substrate 10 of FIG. 14.

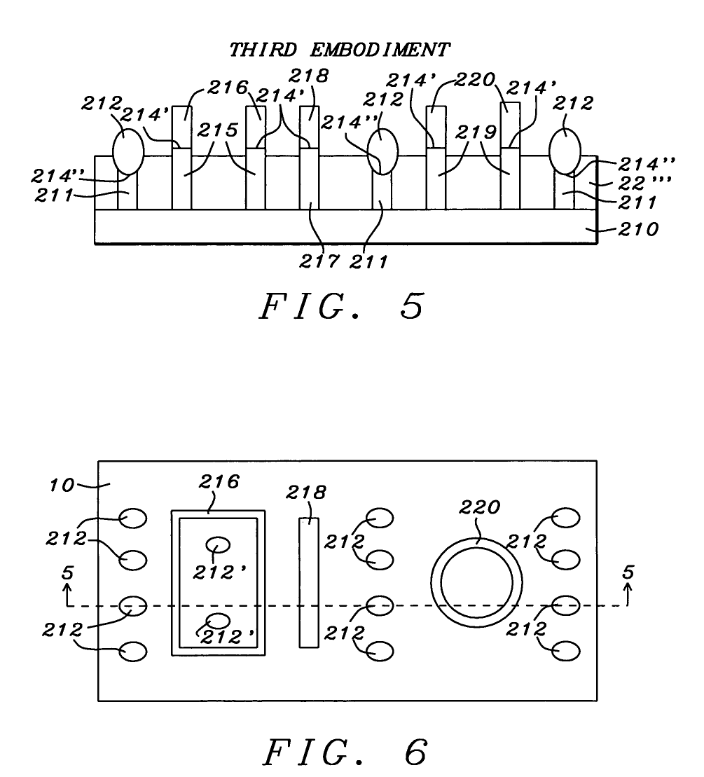

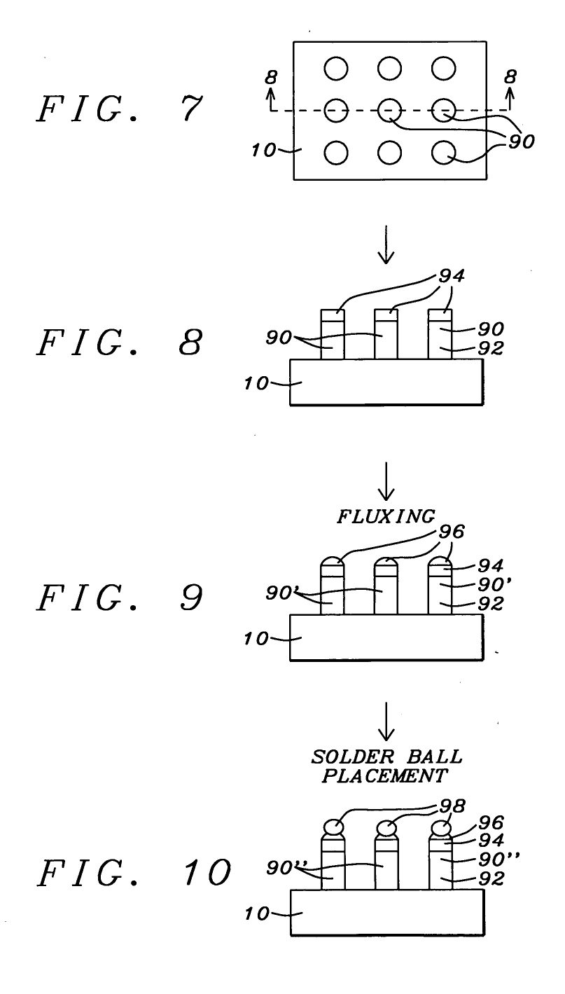

FIG. 7 is an overhead view of FIG. 8 with FIG. 8 being a cross-sectional view of FIG. 7 along line 8-8.

Initial Structure —FIGS. 7 and 8

FIGS. 7 and 8 include inchoate bump structures 90 formed over a wafer/die/chip substrate 10 that may have various initial shapes (see FIGS. 1 to 6 and the descriptions herein).

Inchoate bump structures 90 each include a lower pillar metal portion 92 preferably comprised of conductive metals with non-re-flowed characteristics, the ability to be coated with other metals or high melting point characteristics and more preferably the ability to be coated with other metals and having a height of preferably from about 65 to 120 μm and more preferably form about 65 to 85 μm; with an upper portion 94 preferably comprised of eutectic solder or lead free solder and having a thickness of preferably from about 35 to 60 μm and more preferably form about 35 to 40 μm.

It is noted that, while not specifically shown in FIGS. 7 to 15 for simplicity and ease of understanding, the final single composite bump structure(s) 90′″ may comprise two sets of overall heights—see FIGS. 5 and 6 (the third embodiment); and 16 and 17 and those relevant descriptions.

Fluxing—FIG. 9

As shown in FIG. 9 in a fluxing step, flux 96 is formed over the respective upper portions 94 to a thickness of preferably from about 1 to 10 μm and more preferably from about 5 to 7 μm to form first intermediate inchoate bump structures 90′. Flux 96 is preferably water soluble.

Solder/Solder Ball 98 Placement—FIG. 10

As shown in FIG. 10, respective solder/solder balls 98 is/are formed over the flux 96 to form second intermediate inchoate bump structures 90″. Solder/solder balls 98 are preferably comprised of eutectic or lead-free solder. Solder Balls 98 can also be formed using solder paste printing (eutectic or lead-free solder). No ball placement is required for solder paste.

Reflow —FIG. 11

As shown in FIG. 11, the solder/solder balls 98 are subjected to a reflow process to form reflowed solder/solder balls 98′, define solder lines 14 and to form final bump structures 90′″. The reflow process is preferably at a temperature of from about 100 to 260° C. and from about 5 to 10 minutes and more preferably from about 5 to 7 minutes.

Epoxy 22 Coating —FIG. 12

As shown in FIG. 12, an initial layer of epoxy 22 is formed over the wafer/die/chip substrate 10 and the final bump structures 90′″ (bump structures 11, 15, 17, 19; 211, 215, 217, 219) so as to at least cover the final bump structures 90′″. The initial epoxy layer 22 is preferably formed by spin coating, i.e. coating the epoxy onto the wafer/die/chip substrate 10 by means of spinning/rotary motion wherein the epoxy is poured onto the center of the wafer/die/chip substrate 10 with the aid of an epoxy volume dispenser or equivalent, and then spinning the wafer/die/chip substrate 10 to evenly distribute the epoxy over the wafer/die/chip substrate 10 and at least over the final bump structures 90′″ to form initial epoxy layer 22.

Plasma Etch—FIG. 13

As shown in FIG. 13, the wafer/die/chip substrate 10 is placed in a plasma etching machine and a plasma etch is used to etch the initial epoxy layer 22 to a predetermined thickness, that is to:
etch epoxy layer 22 down to above the solder lines 14 to form final epoxy layer 22′ of the first embodiment (see FIGS. 1 and 2);
etch epoxy layer 22 down to below the solder lines 14 to form final epoxy layer 22″ of the second embodiment (see FIGS. 3 and 4); or
etch epoxy layer 22 to form final epoxy layer 22′″ that is above some solder lines (214″) and below other solder lines (214′) (not shown in FIGS. 13 to 15 for simplicity).

The plasma etch preferably employs oxygen and CF₄ (Tetrafluoromethane) ions. The plasma etch is conducted at the following parameters:
RF power: preferably from about 1000 to 1200 Watts; and more preferably from about 1000 to 1200 Watts; and
temperature: preferably from about 60 to 100° C.; and time: preferably from about 15 to 20 minutes and more preferably about 15 minutes.

The completes formation of the epoxy coated 22′/22″ wafer/die/chip substrate 10 as shown in FIGS. 13 and 14.

Sawing the Wafer/Die/Chip—FIG. 15

As shown in FIG. 15, the epoxy coated 22′/22″ wafer/die/chip of FIG. 14 is sawed to form completed wafer level-chip scale packages (WL-CSP) 100.

As discussed above, the final bump structures 90′″ of the wafer level-chip scale packages (WL-CSP) 100 are preferably composed of two sets of final bump structures 90′″: one having a first height (90″′A) and the other having a second height (90″′B) that is less than the first height (the third embodiment) for stacked die or multi-tier substrates (IC or MEMS applications).

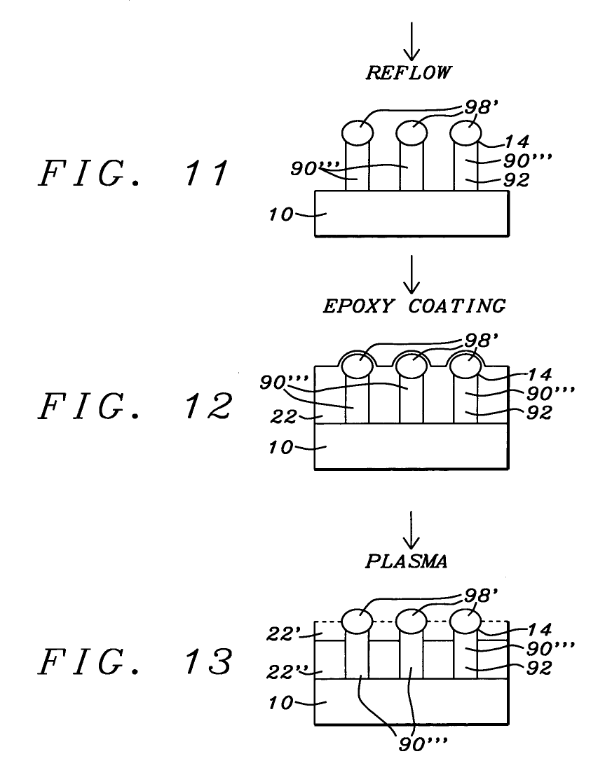

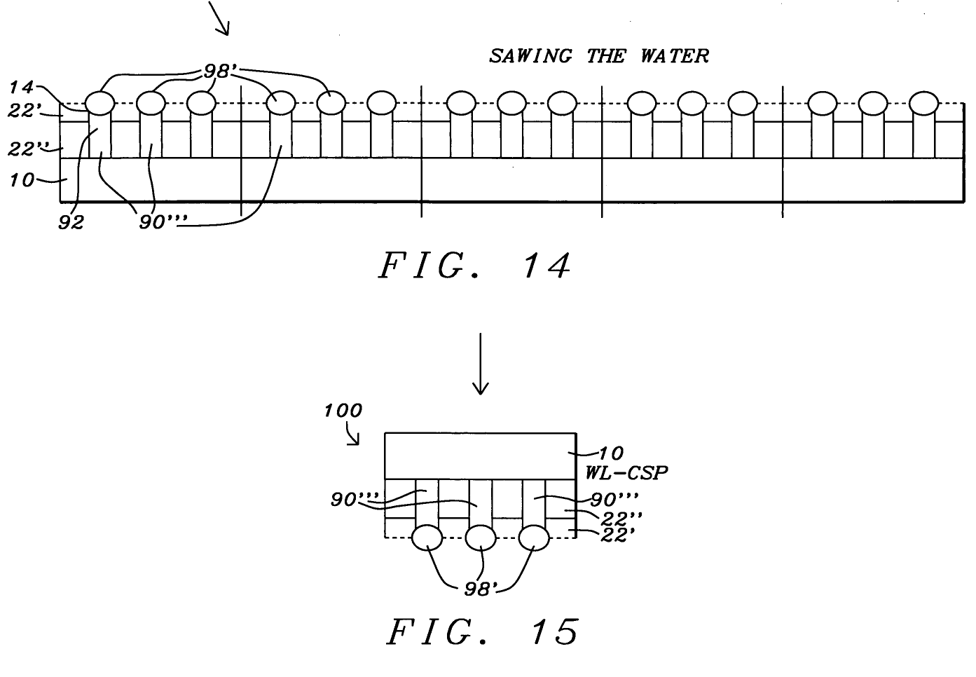

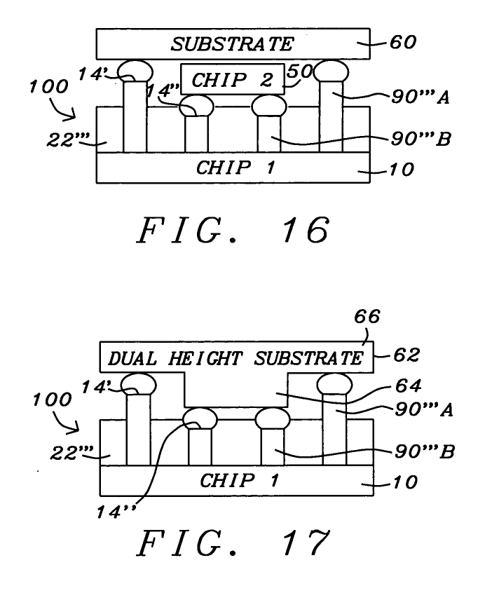

This is more easily appreciated in FIGS. 16 and 17 as now discussed.

Stack Die/Chip Mounting With Variable Height Bumps 90′″—FIG. 16

As shown in FIG. 16, utilizing the wafer level-chip scale packages (WL-CSP) 100 formed in accordance with the present invention having a first set of final bump structures 90″′A having a first height and a second set of final bump structures 90″′B having a second height that is less than the first height on a first chip (CHIP 1), a stack die/chip mounting is achieved.

As shown, the solder lines 14′ of the first set of final bump structures 90″′A is above the top of the epoxy layer 22′″ while the solder lines 14″ of the second set of final bump structures 90″′B is below the top of the epoxy layer 22′″.

Epoxy layer 22′″ is preferably comprised of thermosetting resins or underfill coating material.

A second chip (CHIP 2) 50 is mounted to the second set of final bump structures 90″′B having the second, lower height so that it and the first chip (CHIP 1) are mounted flush with a substrate 60. As shown in FIG. 14, the second chip (CHIP 2) 50 is preferably mounted over the center portion of the first chip (CHIP 1).

Flip Chip Mounted to a Dual Height Substrate—FIG. 17

As shown in FIG. 17, a flip chip employing the dual height final bump structures 90″′A, 90″′B is mounted to a dual height substrate 62 wherein the lower height portion 66 of the substrate 62 mounts to the first set of final bump structures 90″′A having a first height on the flip chip substrate 10′ and the higher height portion 64 of the substrate 62 mounts to the second set of final bump structures 90″′B having a second height on the flip chip substrate 10′ that is less than the first height.

As shown, the solder lines 14′ of the first set of final bump structures 90″′A is above the top of the epoxy layer 22′″ while the solder lines 14″ of the second set of final bump structures 90″′B is below the top of the epoxy layer 22′″.

### ADVANTAGES OF THE INVENTION

The advantages of one or more embodiments of the present invention include:
1) fast process;
2) requires minimal tooling;
3) various bump shapes and sizes;
4) flexibility of two or more different bump heights;
5) better electrical and thermal performances; and
6) ease of design.

While particular embodiments of the present invention have been illustrated and described, it is not intended to limit the invention, except as defined by the following claims.

1. A die, comprising:
a substrate;
two or more various shaped bump structures formed over the substrate; each of the two or more various shaped bump structures having a solder line; and
an epoxy layer formed over the substrate; the epoxy layer having a top surface wherein:
a) the solder lines are below the top surface of the epoxy layer;
b) the solder lines are above the top surface of the epoxy layer; or
c) some of the solder lines are below the top surface of the epoxy layer and some of the solder lines are above the top surface of the epoxy layer.

2. The die of claim 1, wherein one or more of the two or more various shaped bump structures have a first height and one or more of the two or more various shaped bump structures have a second height that is less than the first height.

3. The die of claim 1, wherein the two or more various shaped bump structures have a round shape, a rectangular shape, a square shape, a bar shape or a circular shape.

4. The die of claim 1, wherein at least one of the two or more various shaped bump structures has a bar shape with a width of from about 40 to 300 μm and a length of up to about 3000 μm.

5. The die of claim 1, wherein at least one of the two or more various shaped bump structures has a round shape with a diameter of from about 40 to 300 μm.

6. The die of claim 1, wherein at least one of the two or more various shaped bump structures has a rectangular shape with a width of from about 40 to 300 μm and a length of from about 300 to 3000 μm.

7. The die of claim 1, wherein at least one of the two or more various shaped bump structures has a rectangular shape with a width of from about 100 to 200 μm and a length of from about 350 to 1200 μm.

8. The die of claim 1, wherein at least one of the two or more various shaped bump structures has a square shape with a width of from about 40 to 300 μm.

9. The die of claim 1, wherein at least one of the two or more various shaped bump structures has a square shape with a width of from about 100 to 200 μm.

10. The die of claim 1, wherein at least one of the two or more various shaped bump structures has a circular shape with an outside diameter of from about 150 to 3000 μm and an outside diameter of from about 100 to 2500 μm.

11. The die of claim 1, wherein at least one of the two or more various shaped bump structures has a square and/or rectangular shape and is employed as an RF shield or a Faraday cage.

12. The die of claim 1, wherein the epoxy layer is comprised of thermosetting resins or an underfill coating material.

13. A die, comprising:
a substrate;
two or more various shaped bump structures formed over the substrate; each of the two or more various shaped bump structures having a solder line; one or more of the two or more various shaped bump structures having a first height and one or more of the two or more various shaped bump structures having a second height that is less than the first height; and
an epoxy layer formed over the substrate; the epoxy layer having a top surface wherein:
a) the solder lines are below the top surface of the epoxy layer;
b) the solder lines are above the top surface of the epoxy layer; or
c) some of the solder lines are below the top surface of the epoxy layer and some of the solder lines are above the top surface of the epoxy layer.

14. The die of claim 13, wherein the two or more various shaped bump structures have a round shape, a rectangular shape, a square shape, a bar shape or a circular shape.

15. The die of claim 13, wherein at least one of the two or more various shaped bump structures has a bar shape with a width of from about 40 to 300 μm and a length of up to about 3000 μm.

16. The die of claim 13, wherein at least one of the two or more various shaped bump structures has a round shape with a diameter of from about 40 to 300 μm.

17. The die of claim 13, wherein at least one of the two or more various shaped bump structures has a rectangular shape with a width of from about 40 to 300 μm and a length of from about 300 to 3000 μm.

18. The die of claim 13, wherein at least one of the two or more various shaped bump structures has a rectangular shape with a width of from about 100 to 200 μm and a length of from about 350 to 1200 μm.

19. The die of claim 13, wherein at least one of the two or more various shaped bump structures has a square shape with a width of from about 40 to 300 μm.

20. The die of claim 13, wherein at least one of the two or more various shaped bump structures has a square shape with a width of from about 100 to 200 μm.

21. The die of claim 13, wherein at least one of the two or more various shaped bump structures has a circular shape with an outside diameter of from about 150 to 3000 μm and an outside diameter of from about 100 to 2500 μm.

22. The die of claim 13, wherein at least one of the two or more various shaped bump structures has a square and/or rectangular shape and is employed as an RF shield or a Faraday cage.

23. The die of claim 13, wherein the epoxy layer is comprised of thermosetting resins or an underfill coating material.

24. The die of claim 13, wherein the two or more various shaped bump structures have two sets of heights.

25. A die, comprising:
a substrate;
two or more various shaped bump structures formed over the substrate; each of the two or more various shaped bump structures having a solder line; the two or more various shaped bump structures having a round shape, a rectangular shape, a square shape, a bar shape or a circular shape; and
an epoxy layer formed over the substrate; the epoxy layer having a top surface wherein:
a) the solder lines are below the top surface of the epoxy layer;
b) the solder lines are above the top surface of the epoxy layer; or
c) some of the solder lines are below the top surface of the epoxy layer and some of the solder lines are above the top surface of the epoxy layer.

26. The die of claim 25, wherein one or more of the two or more various shaped bump structures have a first height and one or more of the two or more various shaped bump structures have a second height that is less than the first height.

27. The die of claim 25, wherein at least one of the two or more various shaped bump structures has a bar shape with a width of from about 40 to 300 μm and a length of up to about 300 μm.

28. The die of claim 25, wherein at least one of the two or more various shaped bump structures has a round shape with a diameter of from about 40 to 300 μm.

29. The die of claim 25, wherein at least one of the two or more various shaped bump structures has a rectangular shape with a width of from about 40 to 300 μm and a length of from about 300 to 3000 μm.

30. The die of claim 25, wherein at least one of the two or more various shaped bump structures has a rectangular shape with a width of from about 100 to 200 μm and a length of from about 350 to 1200 μm.

31. The die of claim 25, wherein at least one of the two or more various shaped bump structures has a square shape with a width of from about 40 to 300 μm.

32. The die of claim 25, wherein at least one of the two or more various shaped bump structures has a square shape with a width of from about 100 to 200 μm.

33. The die of claim 25, wherein at least one of the two or more various shaped bump structures has a circular shape with an outside diameter of from about 150 to 3000 μm and an outside diameter of from about 100 to 2500 μm.

34. The die of claim 25, wherein at least one of the two or more various shaped bump structures has a square and/or rectangular shape and is employed as an RF shield or a Faraday cage.

35. The die of claim 25, wherein the epoxy layer is comprised of thermosetting resins or an underfill coating material.
